(19) United States
(12) Patent Application Publication
(10) Pub. No.: US 2018/0138198 A1
(43) Pub. Date: May 17, 2018

(54) Trench structured vertical mosfet

(71) Applicant: Taihyun Choi, Inchon (KR)

(72) Inventor: Taihyun Choi, Inchon (KR)

(21) Appl. No.: 15/330,918

(22) Filed: Nov. 15, 2016

(51) Int. Cl. H01L 27/118; H01L 29/423; H01L 29/08; H01L 27/06; H01L 29/94

(52) U.S. Cl. CPC H01L 27/11807; H01L 29/4236; H01L 29/0847; H03F 3/45071; H01L 29/945; H01L 2027/11866; H01L 27/0629

(57) ABSTRACT

A trench structured vertical MOSFET has been proposed. The newly suggested structure has many superior features in performance e.g. density, speed, noise, current handling capability, power consumption and in fabrication process. Fully depleted active regions between trench gate electrodes and vertical source and drain regions are formed within an epitaxial layer or a substrate.

The structure is proper for CMOS digital and analog devices, imaging, signal processing, memory, and power devices and may replace many conventional planar structured devices because of its outstanding performances.

### BACKGROUND OF THE INVENTION

This invention relates to the field of semiconductor devices. Particularly, the invention relates to the vertical structures of gate, source, and drain of MOSFET which enables the lateral current flow of the transistor using the vertical channel.

Since the invention of the transistor and the integrated circuits, semiconductor technology continuously has developed as one of the most leading industry enriched human living.

As the device size becomes smaller and smaller, many undesirable effects are shown degrading device performances.

Presently people are interested in three dimensional structures of silicon like stacked ICs and FinFETs to keep developing the technology and solving the device performances in density, power and speed.

Trench MOSFET is one of the innovating structures which can solve the density, speed, and especially power consumption for the coming smart and sustainable world.

FIG. 1 shows the conventional planar p channel MOSFET built on the N substrate 10. The channel 14 is formed between p+ source 15 and drain 11 diffusions under the gate electrode 12 on top of gate oxide 13. As the device size becomes smaller, the channel 14 which has length L and width W shows many deteriorative effects for device operation.

### SUMMARY OF THE INVENTION

The main purpose of the present invention is to obtain a new trench structured vertical MOSFET which has many superior features in performance e.g. density, speed, noise, current handling capability, power consumption and in fabrication process.

Another purpose of the present invention is to obtain a trench structured vertical MOSFET which can introduce multiple gate electrodes to make more efficient and enhanced channel current or charge handling of the device. Compared to the conventional planar structured MOSFET, the current flow mechanism in the trench MOSFET occurs in the vertical channel formed by trench gate electrodes and vertically defined source and drain regions.

Using the vertical dimension of silicon, the increased current, speed, and density would be realized without sacrificing the surface area.

Unlike the conventional planar structured MOSFET which uses one sided gate electrode to form the active channel of the device, the trench MOSFET can introduce multiple gate electrodes to make more efficient and enhanced channel current or charge dealing of the device. By adjusting the vertical dimension, spacing and shape of gate electrodes and vertical diffusions, the current or the charge handling capability is increased indefinitely and the signal manipulation is easier than the planar structure. This larger current or charge handling capacity results in the higher density, smaller and faster devices. Channel of the device which is formed by multiple gate electrodes with the lower gate potential shows the lower power consumption and the higher speed device performances avoiding short channel effects which are pronouncing in small feature size devices.

### BRIEF DESCRIPTION OF DRAWINGS

These and other characteristics of the present invention will become apparent from the following description of some forms of embodiment, given as a non-restrictive example regarding the attached drawings wherein:

FIG. 1 shows a Conventional planar MOSFET;

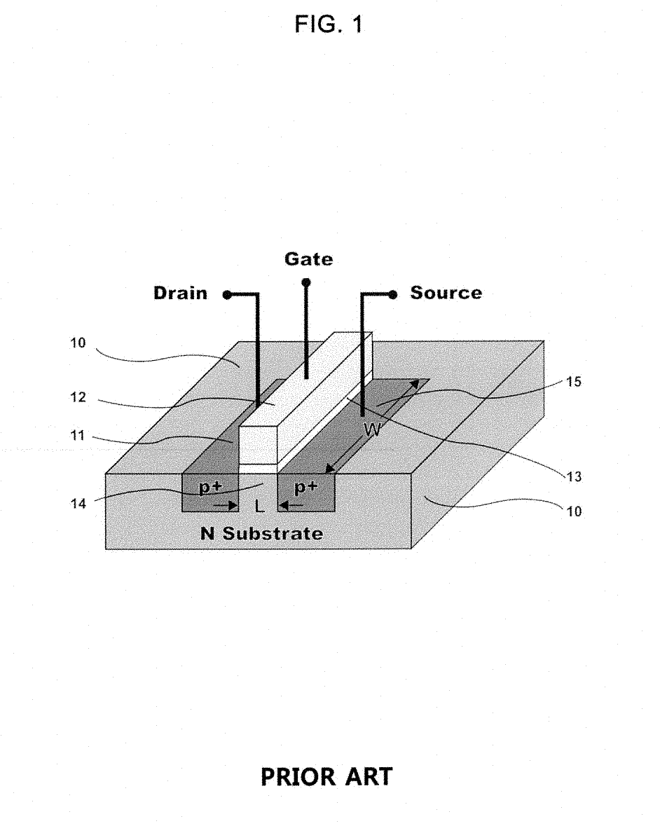

FIG. 2 shows the surface view and the inside view of Trench structured vertical MOSFET in accordance with a possible form of embodiment of the present invention;

FIG. 3 shows the top view of the Trench vertical PMOSFET in N substrate;

FIG. 4 shows the cross-sectional view of the Trench vertical PMOSFET along lines (a)-(a) and (b)-(b) of FIG. 3;

FIG. 5 shows the top view of the Trench vertical NMOSFET in P well;

FIG. 6 shows the cross-sectional view of the Trench vertical NMOSFET along lines (a)-(a) and (b)-(b) of FIG. 5;

FIG. 7 shows a Trench vertical CMOSFET array on P substrate;

FIG. 8 shows a Trench vertical CMOSFET array on N substrate;

FIG. 9 shows the surface view of the Two input trench CMOS NAND gate;

FIG. 10 shows the surface view of the Two input trench CMOS NAND gate without metal layer and trench gate electrodes;

FIG. 11 shows the cross-sectional view of FIG. 10 along line (a)-(a);

FIG. 12 shows the trench CMOS operational amplifier.

### DETAILED DESCRIPTION OF THE INVENTION

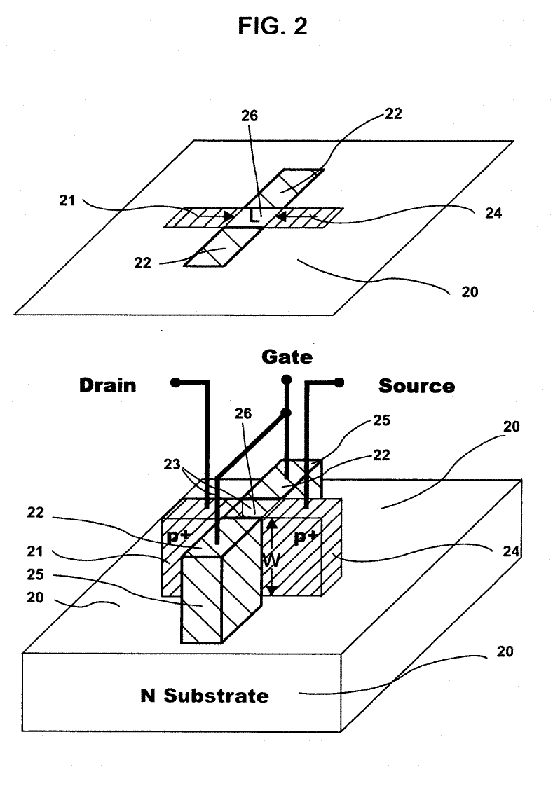

FIG. 2 shows the trench vertical MOSFET surface view and the inside view of the structure built in N substrate 20 with trench gate electrodes 22 and source 24 and drain 21 p+ diffusions formed by ion implantations or by trench formations which are used as source or drain.

The diffusion depth can define the channel 26 width W. Trench gate electrodes 22 can be formed by dry plasma etching deeper than p+ diffusions 21, 24.

After the trench etching the insulating gate materials 23, SiO2 or other material is deposited or thermally grown on the trench walls.

After then, the trenches 25 are filled with conducting material like doped polysilicon to act as gate electrodes 22. The spacing between two diffusions 21, 24 can be defined as the channel 26 length L. By increasing the p+ diffusions 21 and 24 depth and the trench gate electrodes 22 depth, the channel 26 width W can be increased. The channel 26 surrounded by two gate electrodes 22 shows better performances in current handling, speed, leakage so power dissipation than the planar structure because it is formed with relatively lower gate 22 potentials forcing on both sides of the channel 26.

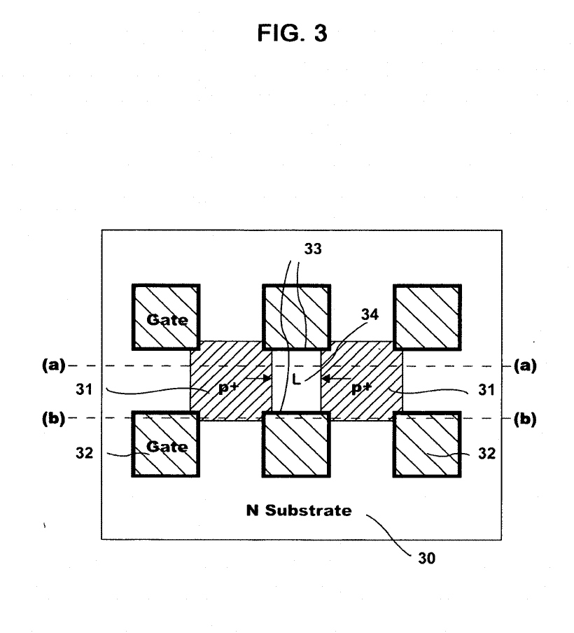

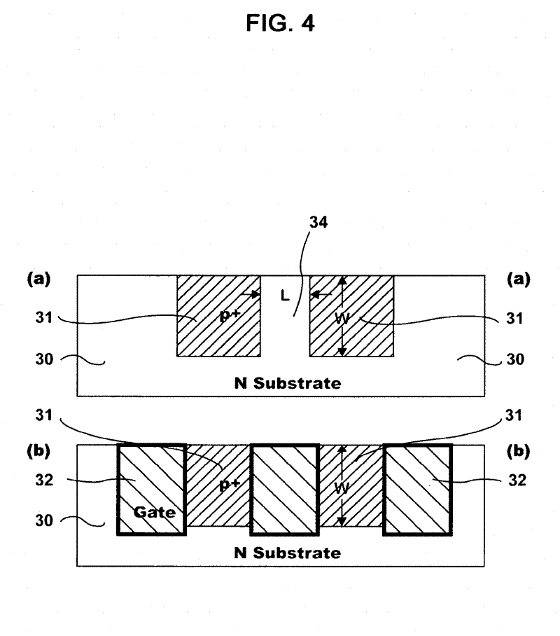

FIG. 3 shows the top view of trench vertical PMOSFET and FIG. 4 shows the cross-sectional view along lines (a)-(a) and (b)-(b) of FIG. 3. N substrate 30 is used to form a p channel MOSFET with gate electrodes 32 surrounded by gate oxide 33 and p+ diffusions 31.

In FIG. 3 and FIG. 4 the channel length L and the channel width W are shown in the channel 34. Introducing multiple gate electrodes 32 and multiple p+ diffusions 31 for the source and the drain region, exact ratios of W/L devices can be made.

In the FIG. 3 top view horizontal and vertical current flows are possible by shaping and controlling gate electrodes 32, source, and drain diffusions 31.

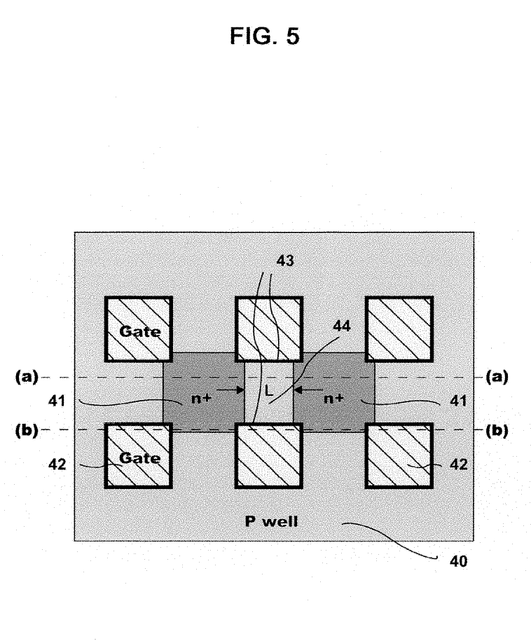

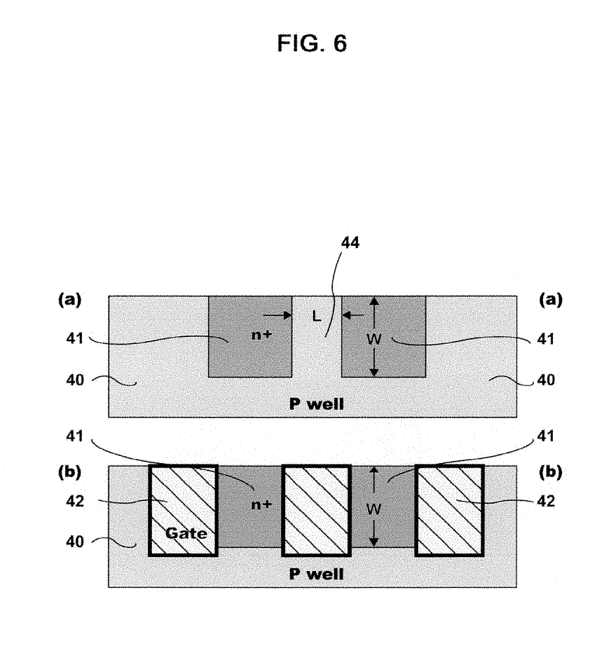

FIG. 5 and FIG. 6 show the top view and the cross-sectional view of the trench vertical NMOSFET. These are the same as FIG. 3 and FIG. 4 except for the opposite polarity of substrate and diffusions to build N channel devices.

P type well 40 is used to make N channel device with n+ diffusions 41 and trench gate electrodes 42.

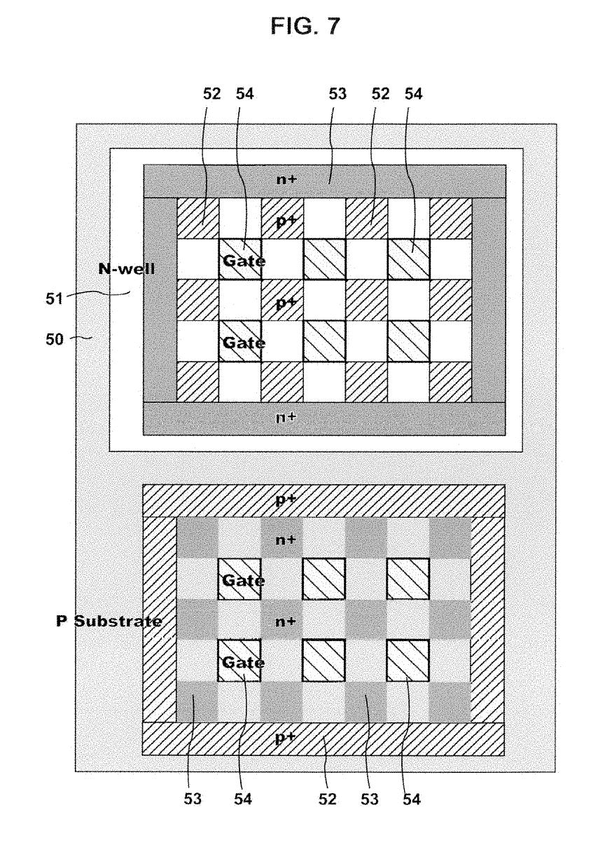

FIG. 7 shows the trench vertical CMOSFET array. P type substrate 50 and N well 51 are used to build NMOSFETs and PMOSFETs, respectively.

N channel devices are formed on P substrate 50 with p+ guard ring 52 which is connected to VSS, trench gate electrodes 54 and n+ diffusions 53 for source and drain regions.

N well 51 is formed on P substrate 50 with n+ guard ring 53 which has the same polarity of n+ diffusions 53 in NMOSFETs and is connected to VDD. p+ diffusions 52 for source and drain of PMOSFETs and trench gate electrodes 54 are formed in N well 51. The array may be used in both analog and digital programmable circuit design which needs exact size of P channel and N channel devices.

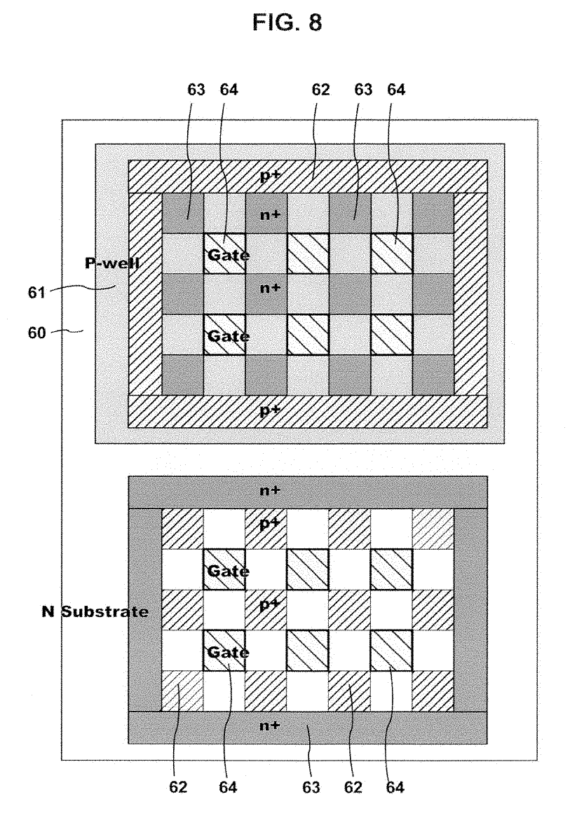

FIG. 8 shows the trench vertical CMOSFET array which is built in N substrate 60. It has the same structure of FIG. 7 except for the opposite polarities of N substrate 60 and P well 61 structures

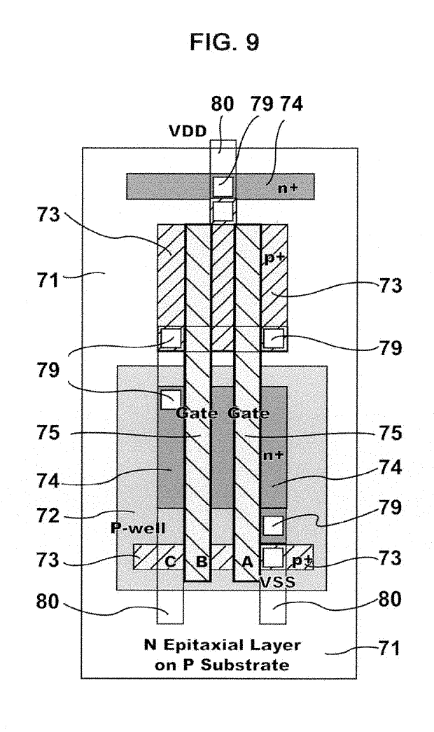

FIG. 9 shows the top view the two-input trench CMOS NAND gate with metal layer. N epitaxial layer 71 on P substrate 70 is used to build p channel MOSFETs and P well 72 to build n channel MOSFETs. P well 72 is grounded to VSS with metal layer 80 through P well bias p+ diffusion 73.

N epitaxial layer 71 is biased to VDD with metal layer 80 through n+ diffusion 74. N channel trench gate electrodes 75 in series inputs of A and B and n+ diffusion 74 for sources and drains of series gates are formed in P well 72.

P channel trench gate electrodes 75 in parallel inputs of A and B and p+ diffusion 73 for sources and drains of parallel gates are formed in N epitaxial layer 71.

Both inputs of A and B trench gate electrodes 75 of PMOSFETs and NMOSFETs are connected with polysilicon layers and the output drains of NMOSFETs 74 and PMOSFETs 73 are tied together with the metal layer 80 through contacts 79 as output C.

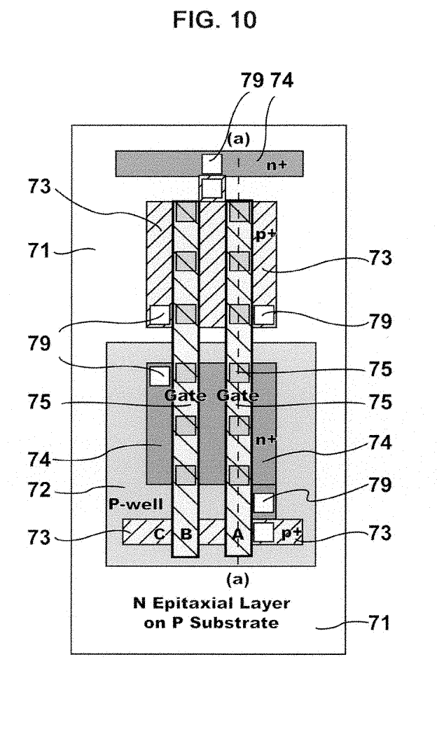

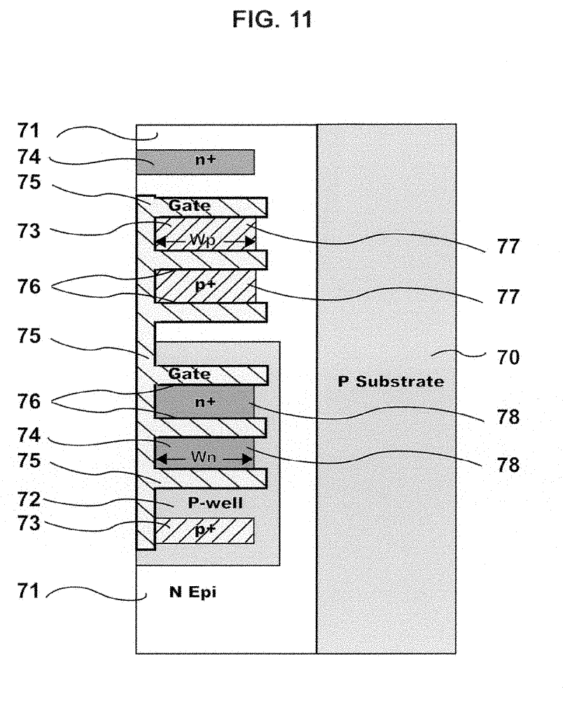

In FIG. 10, the top view of the gate without metal layer and trench gate electrodes is shown. The cross-sectional view of FIG. 10 along line (a)-(a) is shown in FIG. 11. Multiple gate electrodes 75 are introduced to increase the channel widths Wp of PMOSFETs and Wn of NMOSFETs respectively. As is shown in FIG. 11 the PMOSFETs channel 77 and the NMOSFETs channel 78 are fully surrounded by trench gate electrodes 75 covered with gate oxides 76.

When both inputs A and B are applied with high voltages, the channels 78 are fully depleted and inverted to flow the current from the drain to the source region to make NMOSFETs on state with relatively lower voltages and shorter time compared to the one sided conventional planar structured gate because the double-sided trench gate electrodes can make stronger electric fields in the channel regions with lower voltage. In both PMOSFETs, the channel 77 are not formed and the transistors are off states with less leakage which results in shorter switching time and less power consumption than the planar structured gate.

Therefore, output C becomes low state. If anyone input A or B is applied with a low voltage, that PMOSFET is turned on and the equivalent NMOSFET is off state in a relatively shorter time than the planar structured gate. So, the output C becomes high state and the circuit functions as a NAND gate.

Thus, higher performances in speed, power consumption and current gain are shown in the trench structured gate.

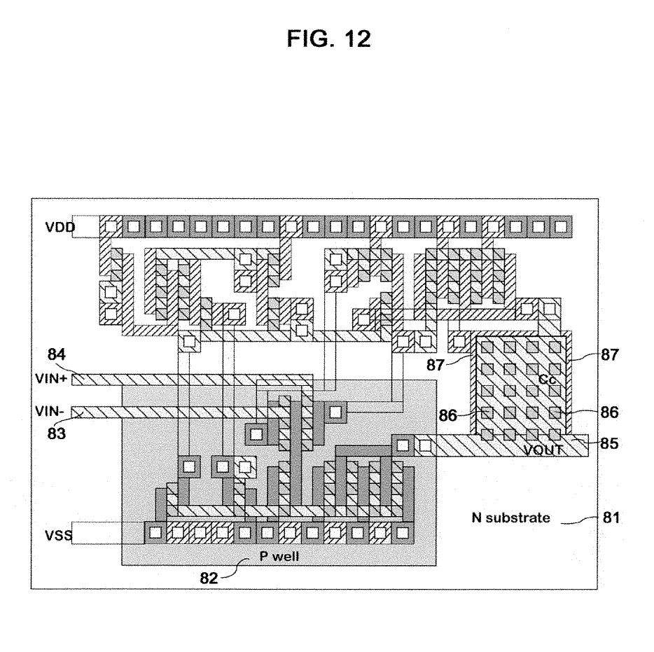

FIG. 12 shows the trench CMOS operational amplifier. The amplifier consists of fifteen transistors and a coupling capacitor. There are two amplifying stages, biasing circuits, and process and temperature compensation circuits.

The PMOSFET circuits are built in N substrate 81 which is biased to VDD through n+ diffusions and NMOSFET circuits are built in P well 82 on N substrate 81. The P well 82 is biased to VSS through p+ diffusions.

Inverting input VIN− 83, non-inverting input VIN+ 84, output VOUT 85, and the coupling capacitor Cc are shown. Output terminal of the capacitor Cc 86 is made of multiple trench polysilicon gate electrodes and the other terminal to the internal circuit is p+ diffusion 87 which is made of multiple diffusions.

Multiple trench gate electrodes and multiple diffusions are used to get larger size of transistors and a capacitor. Precisely sized transistors and capacitors which are needed for the analog circuit design can be relatively easily realized in trench CMOS.

1. A metal oxide semiconductor field effect transistor, MOSFET, comprising:
a semiconductor substrate of a first conductive type as an exposed major surface;
a plurality of space-apart relatively highly doped diffusions of a first and a second conductive type of predefined cross-section formed in the substrate extending from the major surface into the substrate to a predetermined depth;
a plurality of electrode layers formed on top of a plurality of space-apart relatively highly doped diffusions for applying respective voltage signals to work as a source, a drain or a substrate electrode of a MOSFET;
a plurality of space-apart trenches of predefined cross-section formed in the substrate, each extending from the major surface into the substrate to a predetermined depth;
thin insulating layers formed over the major surface and extending into each trench of the plurality of trenches therein to cover inner surfaces of each trench;
a plurality of electrode layers formed on the insulating layer, covering each trench of the plurality of trenches for applying respective voltage signals to work as a gate electrode or plural gate electrodes of a MOSFET.

2. The MOSFET as in claim 1, further comprising a MOSFET of one polarity type and a MOSFET of opposite polarity type to form a complementary metal oxide semiconductor field effect transistor, CMOSFET, by introducing a second conductive type well region in a first conductive type major substrate;
a first conductive type of diffusions for source and drain in the second conductive type well to form a MOSFET of opposite polarity type;
diffusions of a first conductive type in a first conductive type major substrate for substrate bias;
and diffusions of a second conductive type in a second conductive type well region for well bias.

3. The MOSFET as in claim 1 or 2, further comprising multiple diffusions connected with conducting materials to form a larger diffusion, and multiple trench gate electrodes connected with conducting materials to form a larger trench gate electrode.

4. The MOSFET as in claim 1 or 2, further comprising a capacitor with two terminals;
multiple diffusions connected with conducting materials to form a larger diffusion to be used as a terminal of a capacitor;
and multiple trench gate electrodes in the diffusion area connected with conducting materials to form a larger trench gate electrode to be used as the other terminal of a capacitor.
